(19) United States
(12) Patent Application Publication
(10) Pub. No.: US 2012/0097437 A1
(43) Pub. Date: Apr. 26, 2012

(54) Resin Composition, and Prepreg and Printed Circuit Board Prepared Using the Same

(75) Inventors: Shih-Hao Liao, Chupei City (TW); Chih-Wei Liao, Chupei City (TW); Hsuan-Hao Hsu, Chupei Cit (TW); Hsien-Te Chen, Chupei City (TW); Tsung-Hsien Lin, Chupei City (TW)

(73) Assignee: TAIWAN UNION TECHNOLOGY CORPORATION, Chupei City (TW)

(21) Appl. No.: 13/006,530

(22) Filed: Jan. 14, 2011

(30) Foreign Application Priority Data
Oct. 21, 2010 (TW) 099135915

(51) Int. Cl. H05K 1/03; C08K 3/34; C08L 63/00

(52) U.S. Cl. 174/258; 525/417; 523/435; 523/466; 523/400

(57) ABSTRACT

A resin composition is provided. The resin composition comprises:
an epoxy resin;
a polymer solution as a hardener, which is prepared by the following steps:
   (a) dissolving an N,O-heterocyclic compound into a first solvent to form a first reaction solution, wherein the N,O-heterocyclic compound is of Formula I or Formula II:

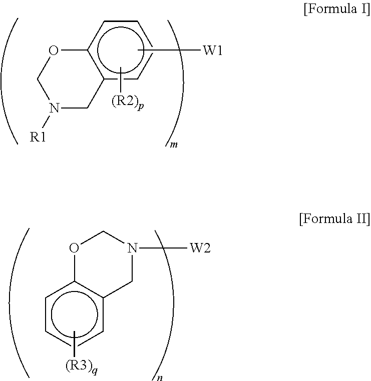

wherein, R1 to R3, W1, W2, m, n, p and q are defined in the specification;
   (b) heating the first reaction solution to a first temperature to carry out a ring-opening polymerization; and
   (c) cooling the first reaction solution to a second temperature to substantially terminate the ring-opening polymerization, and thus obtain the polymer solution, wherein, the first solvent is unreactive to the N,O-heterocyclic compound; the first temperature is higher than the softening temperature of the N,O-heterocyclic compound and lower than the boiling point of the first solvent; and the second temperature is lower than the first temperature, and
      wherein, the amount of the hardener, based on the solid, is about 20 parts by weight to about 200 parts by weight per 100 parts by weight of the epoxy resin.

This application claims priority to Taiwan Patent Application No. 099135915 filed on Oct. 21, 2010.

### CROSS-REFERENCES TO RELATED APPLICATIONS

Not applicable.

### BACKGROUND OF THE INVENTION

1. Field of the Invention

The present invention relates to a resin composition. Specifically, the present invention relates to an epoxy resin composition containing a polymer solution as a hardener, and a prepreg and a printed circuit board prepared with the use of the epoxy resin composition, wherein the polymer is prepared from an N,O-heterocyclic compound.

2. Descriptions of the Related Art

Printed circuit boards are circuit substrates that are used for electronic devices to load other electronic components and electrically connect the components to provide a stable circuit working environment. One kind of conventional printed circuit boards is a copper clad laminate (CCL), which is primarily composed of resin, reinforcing material and copper foil. The resin may be, for example, epoxy resin, novolac resin, polyamine formaldehyde resin, silicone resin or polytetrafluoroethylene resin; and the reinforcing material may be, for example, glass fiber cloth, glass fiber mat, insulating paper or linen cloth.

Generally, a printed circuit broad can be prepared by the following method: immersing a reinforcing material such as a glass fiber fabric into a resin; setting the immersed glass fiber fabric to a half-hardened state, i.e. B-stage, to obtain a prepreg; superimposing certain layers of the prepregs and superimposing a metal foil on at least one external surface of the superimposed prepregs to provide a superimposed object; performing a hot-pressing operation onto the superimposed object, i.e. C-stage, to obtain a metal clad laminate; digging a plurality of holes on the metal clad laminate and plating these holes with a conductive material to form via holes; and finally, etching the metal foil on the surface of the metal clad laminate to form a defined circuit pattern to accomplish the preparation of the printed circuit broad.

In consideration of the subsequent electronic processes, a printed circuit board substrate must be provided with certain thermal resistance, size stability, chemical stability, processability, flexibility, mechanical strength etc. Generally, epoxy resin is the most popular resin in the printed circuit board industry since the printed circuit broad prepared by using epoxy resin can properly meet the above requirements. Epoxy resin is a general name for organic polymer compounds with two or more epoxy groups in the molecular structure, and is a reactive monomer. A highly cross-linked structure can be obtained by polymerizing molecules with high epoxy group content. However, even such a highly cross-linked structure possesses a relatively high hardness and glass transition temperature (Tg) as well as a well chemical resistance, it also possesses a poor impact resistance which is disadvantageous to the subsequent process.

In view of the above, N,O-heterocyclic compounds with a

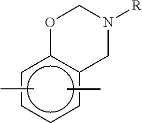

structure are now commonly used as a hardener to regulate epoxy resin. Due to a high proportion of benzene rings and C—N bonds in the structure, the N,O-heterocyclic compounds possess excellent thermal properties (such as thermal resistance, high glass transition temperature and flammability), chemical properties and mechanical properties. In addition, the polymer prepared from a ring-opening polymerization of N,O-heterocyclic compounds has a large number of hydroxyl groups in its structure and can further react with an epoxy resin to provide a final product with improved thermal properties and mechanical properties.

However, in the above method, the ring-opening polymerization of the N,O-heterocyclic compounds and the polymerization of the epoxy resin are performed at the same time, which renders the overall polymerization degree of the polymer uncontrollable and thus results in problems, such as non-uniform product property between every batch and uncontrollable quality.

In view of the above, the present invention provides a resin composition for the preparation of printed circuit boards, which is capable of shortening and controlling the hot-pressing duration. The products prepared by using the resin composition of the present invention are provided with good thermal properties and mechanical properties and a uniform quality.

### SUMMARY OF THE INVENTION

An aspect of the present invention is to provide a resin composition, comprising:
an epoxy resin;
a polymer solution as a hardener, which is prepared by the following steps:
   (a) dissolving an N,O-heterocyclic compound into a first solvent to form a first reaction solution, wherein the N,O-heterocyclic compound is of Formula I or Formula II:

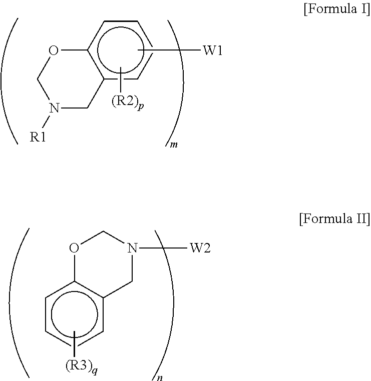

wherein,
R1 to R3 are independently selected from a group consisting of H, a halogen, a substituted or unsubstituted C1-C10 alkyl group, a substituted or unsubstituted C1-C10 cycloalkyl group, and a substituted or unsubstituted C6-C20 aryl group;
W1 and W2 are independently selected from a group consisting of H, a halogen, an ether group, a thioether group, a sulfonyl group, a sulfinyl group, a carbonyl group, a substituted or unsubstituted C1-C10 alkyl group, a substituted or unsubstituted C1-C10 cycloalkyl group and a substituted or unsubstituted C6-C20 aryl group;
m and n are independently integers ranging from 1 to 4;
p is an integer ranging from 1 to 3; and
q is an integer ranging from 1 to 4;
   (b) heating the first reaction solution to a first temperature to carry out a ring-opening polymerization; and
   (c) cooling the first reaction solution to a second temperature to substantially terminate the ring-opening polymerization to obtain the polymer solution, wherein, the first solvent is unreactive to the N,O-heterocyclic compound; the first temperature is higher than the softening temperature of the N,O-heterocyclic compound and lower than the boiling point of the first solvent; and the second temperature is lower than the first temperature,
      wherein, the amount of the hardener, based on the solid, is 20 parts by weight to 200 parts by weight per 100 parts by weight of the epoxy resin.

Another aspect of the present invention is to provide a prepreg prepared by immersing a substrate into the above resin composition and drying the immersed substrate.

Yet another aspect of the present invention is to provide a printed circuit broad prepared by the following steps: superimposing a plurality of the said prepregs and superimposing a metal foil on at least one external surface of the superimposed prepregs to provide a superimposed object; performing a hot-pressing operation to the superimposed object to obtain a metal clad laminate; and patterning the clad metal foil on the metal clad laminate.

To render the above objects, technical features and advantages of the present invention more apparent, the present invention will be described in detail with reference to some embodiments hereinafter.

### BRIEF DESCRIPTION OF THE DRAWINGS

FIG. 1 shows the IR spectrum of the laminate prepared by an embodiment of the resin composition of the present invention illustrated in Example 1.

### DESCRIPTION OF THE PREFERRED EMBODIMENT

The following will describe some embodiments of the present invention in detail. However, without departing from the spirit of the present invention, the present invention may be embodied in various embodiments and should not be limited to the embodiments described in the specification. In addition, unless it is additionally explained, the expressions “a,” “the,” or the like recited in the specification (especially in the claims) should include the singular and the plural forms. Furthermore, unless it is additionally explained, while describing the constituents in the solution, mixture and composition in the specification, the amount of each constituent is counted based on the solids.

Compared with conventional resin compositions comprising a N,O-heterocyclic compound as a hardener, one characteristic of the resin composition according to the present invention resides in comprising a polymer solution prepared from an N,O-heterocyclic compound as a hardener so as to shorten the duration of the hot-pressing process involved in the production of a metal clad laminate and well-control the quality thereof. According to the present invention, an N,O-heterocyclic compound is dissolved into a solvent to form a reaction solution; the reaction solution is then raised to a temperature higher than the softening temperature of the N,O-heterocyclic compound to carry out a ring-opening polymerization without using a catalyst to provide a solution of a polymer with a great amount of hydroxyl groups. With the rapid reaction between the hydroxyl groups and the epoxy resin, the desired hardening effect can be effectively provided during the hot-pressing process for preparing the metal clad laminate and the required duration of the hot-pressing process can be effectively shortened. Furthermore, the length of the hot-pressing duration can be controlled by controlling the polymerization degree of the polymer in the polymer solution to broaden the application of the obtained polymer solution.

Specifically, the resin composition of the present invention comprises a polymer solution as a hardener and an epoxy resin, wherein the polymer solution is prepared by the following steps:
(a) dissolving an N,O-heterocyclic compound into a first solvent to form a first reaction solution;
(b) heating the first reaction solution to a first temperature to carry out a ring-opening polymerization; and
(c) cooling the first reaction solution to a second temperature to substantially terminate the ring-opening polymerization, and thus obtain the polymer solution;
   wherein, the first solvent is unreactive to the N,O-heterocyclic compound; the first temperature is higher than the softening temperature of the N,O-heterocyclic compound and lower than the boiling point of the first solvent; and the second temperature is lower than the first temperature.

In step (a), the N,O-heterocyclic compound has the structure of Formula I or II:

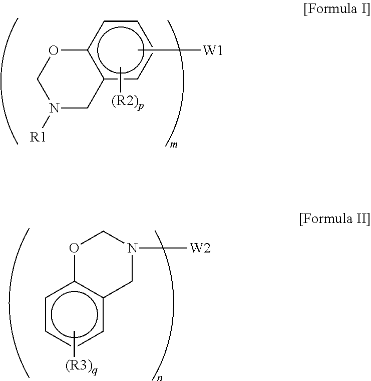

wherein, R1 to R3 are independently selected from a group consisting of H, a halogen (e.g., F, Cl, Br etc.), a substituted or unsubstituted C1-C10 alkyl group, a substituted or unsubstituted C1-C10 cycloalkyl group, and a substituted or unsubstituted C6-C20 aryl group; W1 and W2 are independently selected from a group consisting of H, a halogen, an ether group (e.g., —CH₂OC₂H₅, —CH₂OCH₃, —C₂H₄OCH₃, —O— etc.), a thioether group, a sulfonyl group, a sulfinyl group, a carbonyl group, a substituted or unsubstituted C1-C10 alkyl group, a substituted or unsubstituted C1-C10 cycloalkyl group and a substituted or unsubstituted C6-C20 aryl group; m and n are independently integers ranging from 1 to 4; p is an integer ranging from 1 to 3; and q is an integer ranging from 1 to 4.

In both Formula I and Formula II, m and n are associated with W1 and W2 respectively. For example, in reference to Formula I, without being restricted by any theories, when m is 1, W1 is a group with a single bond, such as H, —F, —Cl, —Br, —CH₃, etc., and the N,O-heterocyclic compound is a compound with one N,O-heterocyclic structure; when m is 2, W1 is a linking group with two bonds and the N,O-heterocyclic compound is a compound with two N,O-heterocyclic structures, and so forth. In the following examples, the illustrated N,O-heterocyclic compounds were provided by means of a chemical synthesis from a phenol compound, an aldehyde compound and an amine compound, as described therein.

In view of the polymerizing difficulty of the N,O-heterocyclic compound and properties of the polymer obtained therefrom, m and n are preferably independently 2 or 3. In this case, W1 and W2 are independently selected from a group consisting of an ether group; a thioether group; a sulfonyl group; a sulfinyl group; a carbonyl group; a C1-C10 alkyl group optionally with one or more substituents independently selected from a group consisting of an ether group, a thioether group, a sulfonyl group, a sulfinyl group and a carbonyl group; a C1-C10 cycloalkyl group optionally with one or more substituents independently selected from a group consisting of an ether group, a thioether group, a sulfonyl group, a sulfinyl group and a carbonyl group; and a C6-C20 aryl group optionally with one or more substituents independently selected from a group consisting of an ether group, a thioether group, a sulfonyl group, a sulfinyl group and a carbonyl group. More preferably, both m and n are 2, and W1 and W2 are independently selected from a group consisting of:

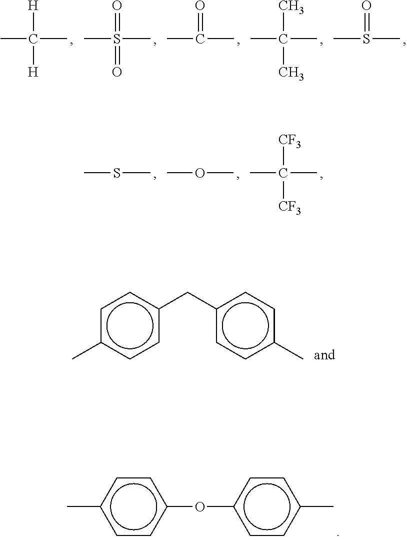

In this case, the N,O-heterocyclic compound has a structure of Formula I′ or Formula II′:

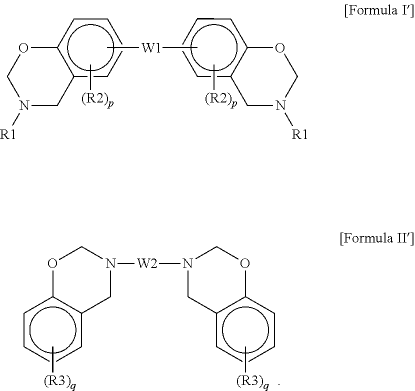

In the following examples,

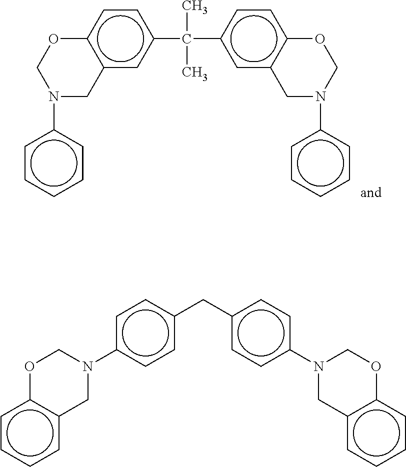

are illustrated as the N,O-heterocyclic compounds.

In step (a), the N,O-heterocyclic compound is dissolved into the first solvent to provide the first reaction solution, wherein the dissolving rate can be increased by heating or stirring. The first solvent may be any inert solvent that can dissolve but un-react with the N,O-heterocyclic compound. The boiling point of the first solvent should be at least higher than the maximum operating temperature involved in the preparation of the desired polymer solution, generally around the temperature for the ring-opening polymerization. The purpose of controlling the boiling point is to avoid the first solvent from escaping during the operation and thus change the concentration of the first reaction solution, which may result in the difficulty for the subsequent process (e.g., the solution may become too thick to stir) or influence the quality of the prepared polymer solution (e.g., the polymerization degree may be non-uniform). Without being restricted by any theories and departing from the above selection conditions, the first solvent, for example, may be a solvent selected from a group consisting of cyclohexanone, toluene, xylene, acetone, butanone, methyl isobutyl ketone, N,N-dimethyl formamide (DMF), N,N′-dimethyl acetamide (DMAc), N-methyl-pyrrolidone (NMP) and combinations thereof. In the following examples, cyclohexanone and DMF are illustrated as the first solvent.

The first solvent can be used in any amount as long as it is sufficient for dissolving the used N,O-heterocyclic compound. In view of the cost efficiency, the amount of the first solvent is generally about 5 parts by weight to about 60 parts by weight, preferably about 20 parts by weight to about 40 parts by weight per 100 parts by weight of the N,O-heterocyclic compound. In the following examples, the amount of the first solvent is 25 parts by weight per 100 parts by weight of the N,O-heterocyclic compound.

In step (b), after the N,O-heterocyclic compound is dissolved into the first solvent to form the first reaction solution, energy is supplied to heat the first reaction solution to a first temperature. The first temperature is at least higher than the softening point of the N,O-heterocyclic compound to carry out the ring-opening polymerization of the N,O-heterocyclic compound to prepare the solution containing the desired polymer without using an expensive, environmentally hazardous catalyst. In addition, the first temperature should be lower than the boiling point of the first solvent to avoid the first solvent from escaping during the operation and then change the concentration of the first reaction solution which may result in difficulty for the subsequent process or influence the quality of the prepared polymer solution. In the following examples, in view of the used N,O-heterocyclic compound and solvent, the first temperature is about 110° C. to about 160° C. In the present invention, with N,O-heterocyclic compounds of Formulae I′ and II′ as an example, the obtained polymers after ring-opening polymerization have structures of Formulae III and IV:

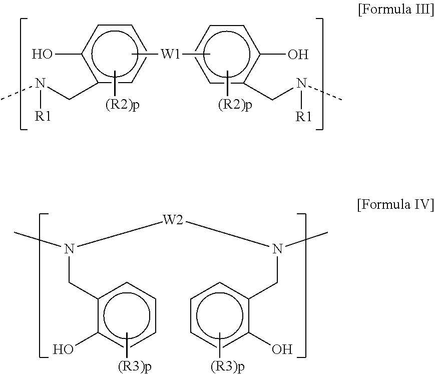

wherein, the energy can be supplied to the first reaction solution to raise the temperature of the first temperature through, for example, thermal energy (such as water bath, oil bath, electrical heater, and heat exchanger), radiant energy (such as UV irradiation and y-ray irradiation) or combinations thereof. In consideration of the heat transfer uniformity and reaction uniformity, it is preferred to stir the first reaction solution during the temperature-raising period.

According to the present invention, the polymerization degree of the polymer in the obtained polymer solution can be regulated by controlling the conditions of the ring-opening polymerization, such as the reaction temperature, reaction time, etc., to effectively control the duration of the hot-pressing process involved in the production of a metal clad laminate wherein the polymer solution of the present invention is used as a hardener, and thus broaden the application of the polymer solution of the present invention. The regulation on the polymerization degree of the polymer can be achieved by monitoring the gel time of the polymer solution during the ring-opening polymerization. When the first reaction achieves the desired polymerization degree, step (c) can be performed subsequently.

In step (c), the first reaction solution is cooled down from the first temperature to a second temperature that is lower than the first temperature by a rapid-cooling manner to substantially terminate the ring-opening polymerization and thus obtain the desired polymer solution. The term “substantially terminate” means that the polymerization between the ring-opened compounds, between the polymers from the ring-opened compounds, or between the ring-opened compounds and the polymers are considerably ceased so that the performance of the prepared product can always meet the user's requirements. The lower the second temperature, the more remarkable the ceasing effect. On the contrary, the higher the second temperature, the less remarkable the ceasing effect. In addition, the faster the cooling rate of the first reaction solution, the smaller the variation of the gel time. Theoretically, the second temperature can be controlled approximately to be the room temperature to avoid the slight variation of the gel time when lowering the temperature from the second temperature to the room temperature, but a higher cooling cost is inevitable (e.g., a relatively great amount of cold solvent may used). Therefore, under the premise that the variation of the gel time during the cooling is acceptable, the second temperature is generally controlled to be below the softening point of the N,O-heterocyclic compound, preferably controlled to be at least 30° C. below the first temperature, and more preferably controlled to be at least 50° C. below the first temperature.

There is no special limitation on the means for cooling in step (c). For example, the cooling can be achieved by carrying out one of the following operations with or without stirring: adding a second solvent into the first reaction solution, subjecting the first reaction solution to a gas atmosphere, subjecting the first reaction solution to a water bath, and combinations thereof, wherein the temperatures of the second solvent, the gas atmosphere and the water bath should be at least lower than the second temperature. To achieve the desired rapid-cooling effect, it is preferred to carry out the cooling by adding a second solvent into the first reaction solution (taken alone or in combination with other cooling means). In this manner, the added second solvent not only can come into contact with the first reaction solution directly to achieve the rapid-cooling effect, but can also dilute the concentration of the polymer and further prevent the polymerized N,O-heterocyclic compound from precipitation due to oversaturation during the process of cooling or at the storage temperature. In the following examples, a rapid-cooling is achieved by adding a second solvent into the first reaction solution.

In the case of adding a second solvent into the first reaction solution to terminate the ring-opening polymerization in step (c), the second solvent may be the same as or different from the first solvent, and may be any solvents which are unreactive with the ring-opened polymer. For example, the second solvent may be a polar solvent selected from a group consisting of toluene, xylene, acetone, butanone, methyl isobutyl ketone, cyclohexanone, N,N-dimethyl formamide and combinations thereof. In the following examples, acetone and butanone are illustrated as the second solvent to substantially terminate the ring-opening polymerization. Under the premise of being capable of providing the desired second temperature to substantially terminate the ring-opening polymerization, there is no special limitation on the amount and temperature of the second solvent.

The polymer solution in the resin composition of the present invention is prepared by the above steps. No precipitation from the polymer solution will occur even when the solution is stored for a long period of time. Furthermore, since the N,O-heterocyclic compound in the polymer solution has been pre-polymerized into a polymer with hydroxyl groups, as compared with a conventional resin composition containing a N,O-heterocyclic compound as a hardener (e.g., benzoxazine), the required hot-pressing period of using the resin composition of the present invention, which contains the polymer solution as a hardener, is shorter. In addition, the resin composition of the present invention is much more practicable since the duration of hot-pressing can be adjusted by adjusting the gel time of the polymer solution (i.e., adjusting the gel time of the polymer in the polymer solution), depending on the requirement of the user.

The epoxy resin contained in the resin composition of the present invention is a resin with at least two epoxy groups in the molecular structure, such as a novolac epoxy resin, a phosphorus-containing epoxy resin etc. In the following examples, 9,10-dihydro-9-oxa-10-phosphaphenanthrene-10-oxide (DOPO) and novolac epoxy resin are illustrated as the epoxy resin.

In the resin composition of the present invention, the amount of hardener can be regulated depending on the user's requirements. Generally, in view of the production cost, the amount of the hardener is preferably, but not limited, 20 parts by weight to 200 parts by weight, more preferably 70 parts by weight to 90 parts by weight, per 100 parts by weight of the epoxy resin based on the solids. In addition, without being restricted by any theories, other hardeners can be incorporated into the resin composition of the present invention to provide specific effects. For example, as shown in the following examples, the resin composition of the present invention can be used along with a non-ring-opened benzoxazine. The amount of benzoxazine can be adjusted depending on the user's requirements. For example, benzoxazine can be used in an amount of 10 parts by weight to 50 parts by weight per 100 parts by weight of epoxy resin.

The resin composition of the present invention may further comprise other additives. For example, a hardening promoter selected from the following group, but not limited to, may be added to provide an improved hardening effect: 2-methyl-imidazole (2MI), 2-ethyl-4-methyl-imidazole (2E4MI), 2-phenyl-imidazole (2PI) and combinations thereof. The amount of the hardening promoter is generally 0.01 parts by weight to 1 part by weight per 100 parts by weight of the epoxy resin. And, a filler selected from the following group, but not limited to, may be added to improve the properties of the epoxy resin such as the processability, flammability, thermal resistance, moisture resistance: silica, glass powder, talcum, kaolin, pryan, mica and combinations thereof. The amount of filler is generally 0.01 parts by weight to 80 parts by weight per 100 parts by weight of the epoxy resin.

In addition to the hardening promoter and filler, the other conventional additives may be added into the resin composition of the present invention depending on needs, such as a dispersing agent (e.g., a silane coupling agent), a mold-release agent, a flame retardant, a toughening agent, wherein the additives can be taken alone or in combination.

The resin composition of the present invention may be prepared into varnish form by evenly mixing the epoxy resin, the polymer solution as a hardener and the optionally added filler through a stirrer; and dissolving or dispersing the mixture into a solvent, for subsequent applications.

The present invention further provides a prepreg which is prepared by immersing a substrate (a reinforcing material) into a varnish from the resin composition of the present invention and drying under appropriate drying conditions. A conventional reinforcing material includes a glass fiber cloth (glass fiber fabric, glass fiber paper, glass fiber mat, etc.), a kraft paper, a short fiber cotton paper, a nature fiber cloth, an organic fiber cloth, etc. In the following examples, 7628 glass fiber cloths are illustrated as the reinforcing materials, and the reinforcing materials are heated and dried at 180° C. for 2 to 10 minutes (B-stage) to provide prepregs in a half-hardened state.

Moreover, the present invention also provides a printed circuit broad which is prepared by the following process: superimposing a plurality of the said prepregs and superimposing a metal foil (such as copper foil) on at least one external surface of the superimposed prepregs to provide a superimposed object; performing a hot-pressing operation onto the object to provide a metal clad laminate; and patterning the clad metal foil.

The present invention will be further illustrated by the embodiments hereinafter, wherein the measuring instruments and methods are respectively as follows:

[Gel Time]

The method for testing the gel time comprises the following steps: getting 0.2 g of polymer solution as a sample and subjecting the sample to form a disc (2 cm² in area) on a hot plate at 200° C.; and calculating the time required for stirring the sample with a stirring rod until it does not adhere to the stirring rod or until it is going to be cured. The time required is regarded as the gel time.

[Hygroscopicity Test]

The hygroscopicity of the laminate is tested by pressure cooker test (PCT), i.e., subjecting the laminate into a pressure container (121° C., 100% R.H. and 2 atm) for 1 hr.

[Solder Floating Test]

The method for testing the solder floating endurance comprises: immersing a dried laminate in a solder bath at 288° C. for a while and observing whether there is any defect such as delaminating and expansion.

[Peeling Strength Test]

The peeling strength refers to the adhesive force of the clad metal foil to the substrate. The adhesive force is generally expressed by the force required for vertically peeling the clad copper foil with a width of one inch (25.4 mm) from the surface of the substrate. The passing standard of a substrate with 1 oz copper foil is 4 lb_{f}/in according to MIL-P-55110E.

[Glass Transition Temperature Test]

The glass transition temperature is measured by a dynamic mechanical analyzer (DMA), wherein the measuring regulations are IPC-TM-650.2.4.25C and 24C testing method of Institute for Interconnecting and Packaging Electronic Circuits (IPC).

[Thermal Decomposition Temperature Test]

The thermal decomposition temperature test is carried out by measuring the mass loss of the sample with a thermogravimetric analyzer (TGA). The temperature where the mass loss is up to 5% is regarded as the thermal decomposition temperature.

[Flammability Test]

The flammability test is carried out according to UL94V (Vertical Burn), which comprises the burning of a laminate, which is held vertical, using a Bunsen burner to obtain its self-ignition and combustion-supporting properties. The result is classified from UL94V-0 (the best) to UL94V-2.

[Toughness Test]

The method for testing the toughness comprises the following steps: laying the laminate on a plane fixture; vertically placing a cross metal jig to come into contact with the surface of the laminate while applying a vertically-applied pressure to the cross metal jig; removing the cross metal jig; and observing the cross trace on the substrate. The laminate without any white embossing lines is regarded as having good toughness, the one with slight white embossing lines is regarded as having normal toughness, and the one with cracks or rupturing one is regarded as having poor toughness.

[Dielectric Constant (Dk) and Dissipation factor (Df) Measurement]

Dk and Df are measured according to ASTM D150 under an operating frequency of 1 GHz.

### EXAMPLES

### The Preparation of N,O Heterocyclic Compound

784 g of bisphenol A, 458 g of aniline and 600 g of toluene were charged into a 3 L separable four-neck flask to form a synthetic solution. The four-neck flask was equipped with a heating device, a thermometer, a stirrer, a cooling pipe, a dropper and a decompression recovery device. The synthetic solution was heated to a temperature of about 40° C. and stirred evenly. While stirring, 809 g of 44% formaldehyde in toluene was dropped into the synthetic solution in 20 minutes, and at this time, the temperature of the synthetic solution was raised to about 90° C. The synthetic solution was then heated and kept at about 90° C. and reacted for 3 hours. Without being limited by theories, it is believed that the reaction is as follows.

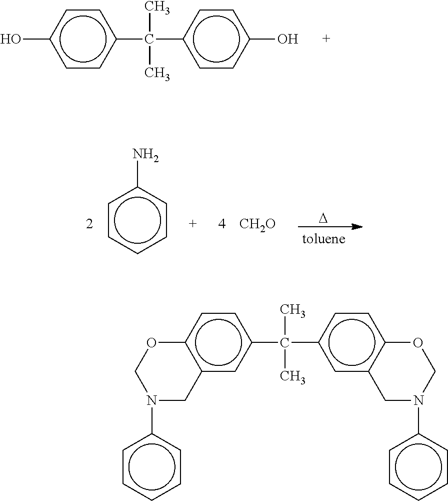

After, the heating and stirring are discontinued for about 20 minutes, after which the synthetic solution was separated into two layers; the water phase and the trace amount of emulsion in the upper layer were removed. Instantly, the synthetic solution was again heated to about 90° C. and the solvent therein was recovered by a decompressing manner (the pressure was lower than about 90 mmHg). After the temperature was raised to about 130° C. and the solvent was completely recovered, about 1380 g of N,O-heterocyclic compound 1 was obtained.

Once more, the synthetic solution was changed to the following combination: 564 g of phenol, 594 g of diaminodiphenylmethane (MDA) and 600 g of toluene. The procedures for preparing N,O-heterocyclic compound 1 were prepared and about 1288 g of N,O-heterocyclic compound 2 was obtained. Without being limited by theories, it is believed that the reaction is as follows.

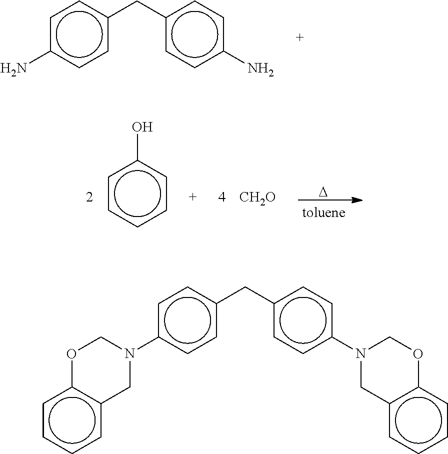

[The preparation of the Polymer Solution of N,O Heterocyclic Compound]

450 g of N,O-heterocyclic compound 1 and 115 g cyclohexanone were charged into a 1 L four-neck flask, which was equipped with a heating device, a thermometer, a stirrer, a cooling pipe, a dropper and a decompression recovery device. The resultant mixture was heated to 70° C. and then kept at 70° C. while stirring until N,O-heterocyclic compound 1 was completely dissolved. Next, the temperature of the resultant mixture was raised to 150° C. to perform the ring-opening polymerization. After reacting for 300 minutes, butanone (185 g, 25° C.) was added to rapidly lower the temperature of the resultant solution to 94° C., and then cooled to room temperature by natural cooling to terminate the ring-opening polymerization. Polymer solution 1-1 (polymer content: about 60 wt %) was obtained. The gel time at 200° C. of polymer solution 1-1 was about 200 sec.

Once more, the preparation procedures the same as above were repeated except for regulating the polymerization times to be 315 and 330 minutes respectively. Polymer solution 1-2 (polymer content: about 60 wt %) and polymer solution 1-3 (polymer content: about 60 wt %) were obtained respectively. The gel times at 200° C. of polymer solutions 1-2 and 1-3 were about 170 sec and about 150 sec, respectively.

A similar preparation procedure was carried out to prepare polymer solution 2. In detail, 1293 g of N,O-heterocyclic compound 2 and 322 g of DMF were charged in a 1 L four-neck flask, which was equipped with a heating device, a thermometer, a stirrer, a cooling pipe, a dropper and a decompression recovery device. The resultant mixture was heated while stirring until the N,O-heterocyclic compound 2 was dissolved completely. Next, the temperature of the resultant mixture was raised to 110° C. to perform a ring-opening polymerization. After reacting for 250 minutes, acetone (about 540 g, 25° C.) was added to rapidly lower the temperature of the resultant solution to 78° C., and then cooled to room temperature by natural cooling to terminate the ring-opening polymerization. Polymer solution 2 (polymer content: about 60 wt %) was obtained. The gel time at 200° C. of polymer solution 2 was about 200 sec.

### The Preparation of the Resin Composition

### Example 1

According to the preparations shown in Table 1, 100 parts by weight of DOPO epoxy resin(Kolon chemical; KOLON 5138), 0.5 parts by weight of 2-methyl-imindazole, 0.5 parts by weight of epoxy type silane coupling agent (Shin-Etsu Chemical; KBM-403), 20 parts by weight of phosphazene flame retardant (Otsuka Chemical; SBP-100), 50 parts by weight of talcum and 80 parts by weight of polymer solution 1-1 (based on the solid) were mixed in room temperature with a stirrer for 60 minutes; and then 80 parts by weight of butanone was added. After mixing the resultant mixture in room temperature for 120 minutes, resin composition 1 was obtained.

### Example 2

The preparation procedures of Example 1 were repeated except for using 80 parts by weight of polymer solution 1-2 (based on the solid) to replace polymer solution 1-1 as the hardener, as shown in Table 1. Resin composition 2 was obtained.

### Example 3

The preparation procedures of Example 1 were repeated except for using 80 parts by weight of polymer solution 1-3 (based on the solid) to replace polymer solution 1-1 as the hardener, as shown in Table 1. Resin composition 3 was obtained

### Example 4

The preparation procedures of Example 1 were repeated except for using 80 parts by weight of polymer solution 2 (based on the solid) to replace polymer solution 1-1 as the hardener, as shown in Table 1. Resin composition 4 was obtained.

### Example 5

The preparation procedures of Example 1 were repeated except for using 40 parts by weight of polymer solution 1-1 (based on the solid) and 40 parts by weight of benzoxazine as the hardener, as shown in Table 1. Resin composition 5 was obtained.

### Example 6

The preparation procedures of Example 1 were repeated except for using 100 parts by weight of novolac epoxy resin (Kolon chemical; KOLON 1138) to replace DOPO epoxy resin, as shown in Table 1. In addition, since the novolac epoxy resin is more flammable than DOPO epoxy resin, a relatively large amount (40 parts by weight) of the phosphazene flame retardant is used in Example 6. Resin composition 6 was obtained.

### Comparative Example

The preparation procedures of Example 1 were repeated except for using 80 parts by weight of benzoxazine to replace polymer solution 1-1 as the hardener, as shown in Table 1. Comparative resin composition 1 was obtained.

[The Preparation of the Printed Circuit Broad]

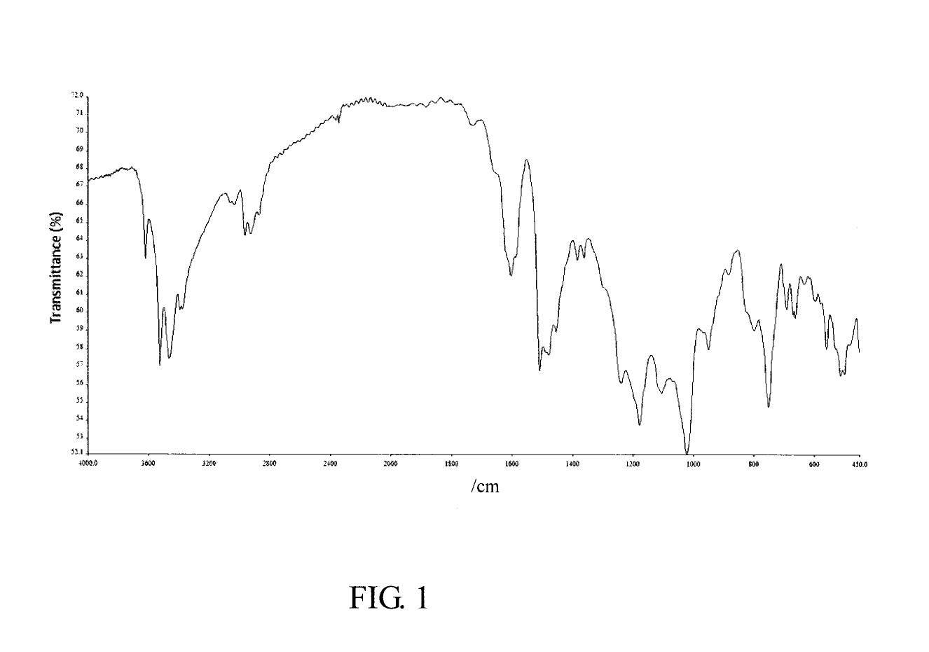

The printed circuit broads were prepared by using the resin compositions of Examples 1 to 6 and Comparative Example 1, respectively. In detail, the preparation of the printed circuit broads is as follows. The resin composition of one of Examples 1 to 6 and Comparative Example 1 was coated on a plurality of 7628 glass fiber cloths (resin/glass fiber cloth: 43%). The coated 7628 glass fiber cloths were then placed in a dryer and dried at 180° C. for 2 to 10 minutes to prepare prepregs in half-hardened state. Four pieces of the prepregs were superimposed and two copper foils were respectively superimposed on the two external surfaces of the superimposed prepregs to provide a superimposed object. A hot-pressing operation was performed onto the superimposed object to provide a metal clad laminate, wherein the hot-pressing conditions are as follows: raising the temperature to 190° C. with a raising rate of 2.0° C./min, and hot-pressing for 60 minutes under the full pressure of 15 kg/cm² (the initial pressure is 8 k g/cm²) at 190° C. Finally, the clad copper foils were patterned to form a circuit pattern to obtain the desired printed circuit broad. FIG. 1 shows the result of the IR spectrum of the laminate prepared by using resin composition 1 of Example 1.

The hygroscopicity, solder floating endurance, peeling strength, glass transition temperature, thermal decomposition temperature, flammability, toughness, dielectric constant, dissipation factor and hot-pressing duration of the printed circuit broads prepared by using the epoxy resin compositions of Examples 1 to 6 and Comparative Example 1 are respectively shown in Table 1.

TABLE 1

| | | | | | | | Comp. |
|---|---|---|---|---|---|---|---|
| | Ex. 1 | Ex. 2 | Ex. 3 | Ex. 4 | Ex. 5 | Ex. 6 | Ex. 1 |
| DOPO epoxy resin | 100 | 100 | 100 | 100 | 100 | — | 100 |
| novolac Epoxy Resin | — | — | — | — | — | 100 | — |
| polymer solution 1-1 | 80 | — | — | — | 40 | 80 | — |
| polymer solution 1-2 | — | 80 | — | — | — | — | — |
| polymer solution 1-3 | — | — | 80 | — | — | — | — |
| polymer solution 2 | — | — | — | 80 | — | — | — |
| benzoxazine | — | — | — | — | 40 | — | 80 |
| 2MI | 0.5 | 0.5 | 0.5 | 0.5 | 0.5 | 0.5 | 0.5 |
| epoxy type silane | 0.5 | 0.5 | 0.5 | 0.5 | 0.5 | 0.5 | 0.5 |
| coupling agent | | | | | | | |
| phosphazene flame | 20 | 20 | 20 | 20 | 20 | 40 | 20 |
| retardant | | | | | | | |
| talcum | 50 | 50 | 50 | 50 | 50 | 50 | 50 |
| butanone | 80 | 80 | 80 | 80 | 80 | 80 | 80 |

The hot-pressing condition: raising the temperature to 190° C. with
a raising rate of 2.0° C./min, and hot-pressing for 60 minutes under
a full pressure of 15 kg/cm² (the initial pressure is 8 kg/cm²)
under 90° C.

| | | | | | | | |
|---|---|---|---|---|---|---|---|
| hygroscopicity | 0.23 | 0.22 | 0.26 | 0.25 | 0.23 | 0.19 | 0.27 |
| (%) | | | | | | | |
| solder floating endurance | >30 | >30 | >30 | >30 | >30 | >30 | >30 |
| (min) | | | | | | | |
| peeling strength | 8.3 | 8.4 | 8.1 | 8.5 | 8.5 | 8.4 | 8.0 |
| (lb_{f}/in) | | | | | | | |
| glass transition | 178.5 | 179.5 | 180.4 | 182.3 | 175.3 | 178.9 | 178.6 |
| temperature (Tg) | | | | | | | |
| (° C.) | | | | | | | |
| thermal decomposition | 378.9 | 374.5 | 374.2 | 376.2 | 377.1 | 374.0 | 375.6 |
| temperature | | | | | | | |
| (° C.) | | | | | | | |
| UL94 level | V-0 | V-0 | V-0 | V-0 | V-0 | V-0 | V-0 |
| toughness | good | good | good | good | good | good | normal |
| dielectric constant | 4.25 | 4.35 | 4.18 | 4.45 | 4.65 | 4.39 | 4.78 |
| (Dk) | | | | | | | |
| (GHz) | | | | | | | |
| dissipation factor | 0.008 | 0.008 | 0.007 | 0.008 | 0.015 | 0.009 | 0.021 |
| (Df) | | | | | | | |
| (GHz) | | | | | | | |
| hot-pressing duration* | 120 | 100 | 90 | 120 | 120 | 120 | 150 |
| (min) | | | | | | | |

*the hot-pressing duration in Table 1 is the duration at 190° C.

As shown in Table 1, compared with conventional resin compositions using benzoxazine as a hardener (Comparative Example 1), the use of resin compositions of the present invention (Examples 1 to 6) can remarkably shorten the hot-pressing duration, and can further control the length of the hot-pressing duration by regulating the constituents of the hardener (Examples 1 to 3) and thus can remarkably increase the flexibility in use. In addition, compared with the printed circuit broads prepared by using benzoxazine as a hardener, the printed circuit broads prepared by using the resin compositions of the present invention possess comparable properties, such as hygroscopicity, solder floating endurance, peeling strength, glass transition temperature, thermal decomposition temperature, flammability, and better toughness and better electric properties (because of a lower Df value).

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A resin composition, comprising:
an epoxy resin;
a polymer solution as a hardener, which is prepared by the following steps:
(a) dissolving an N,O-heterocyclic compound into a first solvent to form a first reaction solution, wherein the N,O-heterocyclic compound is of Formula I or Formula II: 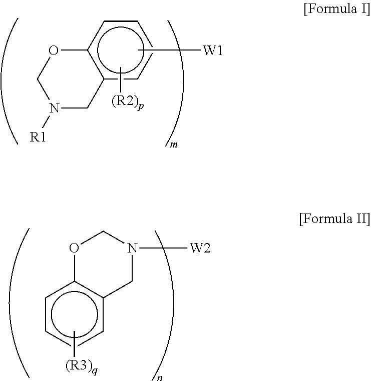
wherein,
R1 to R3 are independently selected from a group consisting of H, a halogen, a substituted or unsubstituted C1-C10 alkyl group, a substituted or unsubstituted C1-C10 cycloalkyl group, and a substituted or unsubstituted C6-C20 aryl group;
W1 and W2 are independently selected from a group consisting of H, a halogen, an ether group, a thioether group, a sulfonyl group, a sulfinyl group, a carbonyl group, a substituted or unsubstituted C1-C10 alkyl group, a substituted or unsubstituted C1-C10 cycloalkyl group and a substituted or unsubstituted C6-C20 aryl group;
m and n are independently an integer ranging from 1 to 4;
p is an integer ranging from 1 to 3; and
q is an integer ranging from 1 to 4;
(b) heating the first reaction solution to a first temperature to carry out a ring-opening polymerization; and
(c) cooling the first reaction solution to a second temperature to substantially terminate the ring-opening polymerization to obtain the polymer solution, wherein, the first solvent is unreactive to the N,O-heterocyclic compound; the first temperature is higher than the softening temperature of the N,O-heterocyclic compound and lower than the boiling point of the first solvent; and the second temperature is lower than the first temperature,
wherein, the amount of the hardener, based on the solid, is about 20 parts by weight to about 200 parts by weight per 100 parts by weight of the epoxy resin.

2. The composition of claim 1, wherein m and n are independently 2 or 3, and W1 and W2 are independently selected from a group consisting of an ether group; a thioether group; a sulfonyl group; a sulfinyl group; a carbonyl group; a C1-C10 alkyl group optionally with one or more substituents independently selected from a group consisting of an ether group, a thioether group, a sulfonyl group, a sulfinyl group and a carbonyl group; a C1-C10 cycloalkyl group optionally with one or more substituents independently selected from a group consisting of an ether group, a thioether group, a sulfonyl group and a sulfinyl group; and a C6-C20 aryl group optionally with one or more substituents independently selected from a group consisting of an ether group, a thioether group, a sulfonyl group and a sulfinyl group.

3. The composition of claim 2, wherein m and n are 2, and W1 and W2 are independently selected from a group consisting of:

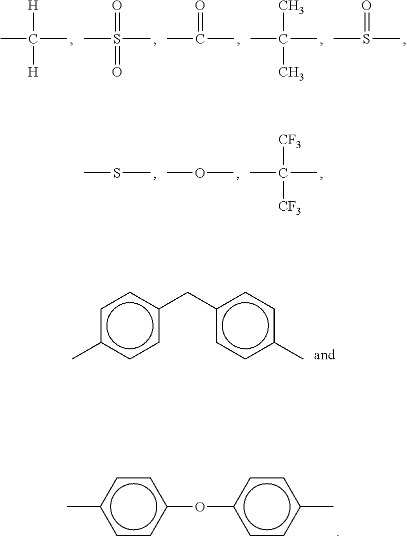

4. The composition of claim 1, wherein in step (a), the amount of the first solvent is about 5 parts by weight to about 60 parts by weight per 100 parts by weight of the N,O-heterocyclic compound.

5. The composition of claim 1, wherein the first solvent is selected from a group consisting of cyclohexanone, toluene, xylene, acetone, butanone, methyl isobutyl ketone, N,N-dimethyl formamide (DMF), N,N′-dimethyl acetamide (DMAc), N-methyl-pyrolidone (NMP) and combinations thereof.

6. The composition of claim 1, wherein the step (c) comprises conducting an operation selected from the following group: adding a second solvent into the first reaction solution, subjecting the first reaction solution to a gas atmosphere, subjecting the first reaction solution to a water bath, and combinations thereof, wherein the temperatures of the second solvent, the gas atmosphere and the water bath are lower than the second temperature, and the second solvent is unreactive to the polymer.

7. The composition of claim 6, wherein the step (c) comprises adding a second solvent into the first reaction solution, and the second solvent is selected from a group consisting of toluene, xylene, acetone, butanone, methyl isobutyl ketone, cyclohexanone, N,N-dimethyl formamide and combinations thereof.

8. The composition of claim 1, wherein the second temperature is at least 30° C. below the first temperature.

9. The composition of claim 1, wherein the second temperature is about room temperature.

10. The composition of claim 1, wherein the amount of the hardener is about 70 parts by weight to about 90 parts by weight.

11. The composition of claim 1, which further comprises benzoxazine.

12. The composition of claim 1, which further comprises a hardening promoter selected from a group consisting of 2-methyl-imidazole (2MI), 2-ethyl-4-methyl-imidazole (2E4MI), 2-phenyl-imidazole (2PI) and combinations thereof, wherein the amount of the hardening promoter is about 0.01 parts by weight to about 1 parts by weight per 100 parts by weight of the epoxy resin.

13. The composition of claim 1, which further comprises a filler selected from a group consisting of silica, glass powder, Talcum, Kaolin, pryan, mica and combinations thereof, wherein the amount of the filler is about 0.01 parts by weight to about 80 parts by weight per 100 parts by weight of the epoxy resin.

14. A prepreg, which is prepared by immersing a substrate into the composition of claim 1 and drying the immersed substrate.

15. A printed circuit board, which is prepared by the following process: superimposing a plurality of the prepreg of claim 14 and superimposing a metal foil on at least one external surface of the superimposed prepregs to provide a superimposed object; performing a hot-pressing operation onto the superimposed object to provide a metal clad laminate; and patterning the clad metal foil.
